(19) United States
(12) Patent Application Publication
(10) Pub. No.: US 2006/0257794 A1
(43) Pub. Date: Nov. 16, 2006

(54) Method for transferring structures from a photomask into a photoresist layer

(76) Inventors: Lars Voelkel, Dresden (DE); Lothar Bauch, Dresden (DE); Patrick Klingbeil, Dresden (DE); Joachim Herpe, Maxhutte-Haidhof (DE); Mirko Vogt, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/408,875

(22) Filed: Apr. 21, 2006

(30) Foreign Application Priority Data
Apr. 22, 2005 (DE) 10 2005 018 737.4

(51) Int. Cl. G03F 7/26

(52) U.S. Cl. 430/315; 430/311

(57) ABSTRACT

A method for transferring structures from a photomask into a photoresist layer is disclosed. In one embodiment, the method involves the patterning of a photoresist layer provided on a layer stack having a topology. In order to suppress standing waves in the photoresist layer and the resist swing effect, which causes variations in the feature sizes, a thin, conformal, organic antireflection layer is applied on the layer stack by means of a known CVD method. The photoresist layer can be patterned dimensionally accurately by means of the method. The method is particularly suitable for the patterning of photoresist layers which are provided for the implantation process of source/drain regions of transistors in semiconductor technology.

### CROSS-REFERENCE TO RELATED APPLICATIONS

This Utility Patent application claims priority to German Patent Application No. DE 10 2005 018 737.4 filed on Apr. 22, 2005, which is incorporated herein by reference.

### FIELD OF INVENTION

The invention relates to a method for transferring structures from a photomask into a photoresist layer, the photoresist layer being arranged above a patterned layer or a patterned layer stack above a semiconductor wafer. The invention also includes a method for introducing a dopant into sections of a layer or a semiconductor wafer.

### BACKGROUND

Microelectronic circuits, such as DRAM (dynamic random access memory) memory cells, for example, have patterned layers which are arranged on a semiconductor wafer and comprise different materials, such as metals, dielectrics or semiconductor material. A photolithographic method is often applied for the patterning of the layers. In this case, a light sensitive photoresist is applied to the layer to be patterned and is exposed to a light radiation in sections by means of a photomask, which has the structures to be transferred into the layer, and a photolithographic imaging device. After a development of the photoresist, the structures are contained in the photoresist as openings in which the layer to be patterned is uncovered.

Photoresist layers applied on topological layers often cannot be patterned with a sufficient quality. By way of example, the openings have sidewalls with an angle of inclination instead of the perpendicular sidewalls that are to be striven for.

A particularly disadvantageous effect is brought about by structures that are not dimensionally accurate in the photoresist during the implantation of source/drain regions of transistors with a dopant.

FIG. 1 illustrates a poorly patterned opening 11 with oblique sidewalls in a photoresist layer 1. The photoresist layer 1 is provided on a patterned layer stack 2 arranged on a semiconductor wafer 3. Gate structures, for example, can be realized with the patterned layer stack 2 and the openings in the photoresist layer 1 are provided for an implantation step by means of which source/drain regions for transistors are introduced into a substrate.

Particularly in the case of oblique implantation, it is scarcely possible to control doping profiles in the case of the photoresist layer that is not patterned dimensionally accurately. A cause of the poor quality of the structures in the photoresist layer is the light that is reflected back at the edges of the patterned layer stack and the underlying layer. As a result of back reflection, standing waves form in the photoresist layer. Depending on thickness fluctuations in the photoresist layer, different amounts of energy are coupled into the photoresist layer, an effect that is also referred to as resist swing. Resist swing results in an undesirable variation in the feature sizes, which may extend up to 180 nm. The problem occurs to an increased extent in the formation of a even smaller structure widths requiring ever thinner photoresist layers.

In order to suppress back reflections and resist swing, provision is usually made of an antireflection layer arranged between the photoresist layer and the layer to be patterned. Commercially available antireflection layers can be applied by means of a spin on method, which, in the case of topological layers, however, leads to thickness fluctuations in the antireflection layer. With conventional materials for the antireflection layer, antireflection layers having a constant thickness cannot be fabricated on the topological layer.

FIG. 2 illustrates an antireflection layer 4 that has been spun onto the patterned layer stack 2. The photoresist layer 1 is provided on the antireflection layer 4. As can be gathered from FIG. 2, the opening 11 in the photoresist layer 1 has perfect perpendicular sidewalls. The antireflection layer 4 would have to be opened for implantation purposes, however, since implantation cannot be effected through it on account of its thickness.

Since the antireflection layer and the combination of antireflection layer and photoresist layer have different thicknesses, an overetching and thus an incipient etching of the patterned layer stack forming the gate structures, for example, may be caused during removal of the antireflection layer by means of an etching process. For this reason, it is not practicable to introduce a conventional antireflection layer in the implantation of source/drain regions.

For these and other reasons, there is a need for the present invention.

### SUMMARY

The present invention provides a method of making a semiconductor, including transferring structures from a photomask into a photoresist layer. In one embodiment, the present invention relates to a method involving the patterning of a photoresist layer provided on a layer stack having a topology. In order to suppress standing waves in the photoresist layer and the resist swing effect, which causes variations in the feature sizes, a thin, conformal, organic antireflection layer is applied on the layer stack by means of a known CVD method. The photoresist layer can be patterned dimensionally accurately by means of the method. The method is particularly suitable for the patterning of photoresist layers which are provided for the implantation step of source/drain regions of transistors in semiconductor technology.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross section through a conventionally patterned photoresist layer.

FIG. 2 illustrates a cross section through a photoresist layer with a conventionally applied antireflection layer.

FIG. 3 illustrates a cross section through a photoresist layer patterned according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a method by which a photoresist layer that is applied on a patterned layer having a topology, or a patterned layer stack, can be patterned dimensionally accurately. The invention includes a method for introducing a dopant into sections of the semiconductor wafer or a layer provided above the semiconductor wafer.

In one embodiment, a method for transferring structures from a photomask into a photoresist layer is provided. In this case, the photoresist layer is arranged above a patterned layer having a topology, or above a patterned layer stack with which the topology is formed. A semiconductor wafer with the patterned layer or the patterned layer stack is made available for carrying out the method. A conformal, organic antireflection layer is provided on the patterned layer or the patterned layer stack. The conformal antireflection layer has the same thickness at all places on the patterned layer or the patterned layer stack. The photoresist layer is applied to the antireflection layer and subsequently exposed with the aid of an imaging device and the photomask. After the development of the photoresist mask, the structures are contained as openings in the photoresist layer.

With the provision of the conformal, organic antireflection layer, that back reflections of the light into the photoresist layer and the formation of standing waves are avoided. Since the conformal antireflection layer is applied uniformly over the entire topology of the underlying layer stack, resist swing brought about by reflections at sidewalls of the layer stack is also suppressed. The openings that form the structures in the photoresist layer can also be patterned cleanly, that is to say without dimensional losses, even for a 193 nm technology. Moreover, the method according to the invention can be used for any desired wavelengths, in particular including the 365 nm and 248 nm technology.

The conformal, organic antireflection layer can be made very thin. Thicknesses in the range of between 10 and 30 nm are striven for. In the case of these thicknesses, implantation can possibly be effected through the antireflection layer. On account of the conformity of the antireflection layer, however, it is also possible to remove the antireflection layer in the openings in the photoresist layer for example by means of an etching step without causing an overetching and hence damage to the underlying layer or the layer stack. The organic antireflection layer can be concomitantly incinerated in a simple manner during the removal of the photoresist layer. The antireflection layer according to the invention thus cannot have a disturbing influence on further processing of the semiconductor wafer.

The conformal antireflection layer is preferably deposited from a gas phase onto the patterned layer or the patterned layer stack. By way of example, a CVD (Chemical Vapor Deposition) method may be applied in order to produce the gas phase. Highly conformal layers having a thickness that is to be predefined can be applied by means of the method. The antireflection layer can be provided in particular in very thin fashion, in the region of 10 nm.

In one embodiment, it is preferred for a carbon compound to be deposited during the CVD method. It is possible for example to use the known method for depositing a carbon hard mask by means of CVD.

In one embodiment, the application of the thin, conformal antireflection layer consists in the use of a pyrolysis method. In the pyrolysis method, a precursor in a solvent is sprayed onto the hot wafer surface. In this case, the precursor is converted in such a way that a thin organic layer is formed and the solvent evaporates. The method makes it possible, in a very simple and uncomplicated manner, to apply a conformal, organic, thin antireflection layer.

In another embodiment, the invention includes a method for introducing a dopant into sections of a semiconductor wafer or a layer provided above the semiconductor wafer. In this case, the patterned layer or the patterned layer stack is provided on the semiconductor wafer or the layer. According to the invention, the described method according to the invention for transferring structures from a photomask into a photoresist layer is applied. An implantation process is carried out in the region of the openings in the photoresist layer, during which implantation process the dopant passes into the sections. The photoresist layer and the antireflection layer are then removed. The method according to the invention has the advantage that very thin photoresist layers such as are used for example for an oblique implantation and the formation of ever smaller structure widths can be patterned cleanly. The formation of dimensionally accurate openings with perpendicular sidewalls in the photoresist layer enables an oblique implantation.

Preferably, after the development of the photoresist layer and prior to the implantation process, the antireflection layer is removed in the openings in the photoresist layer. This may be carried out by means of a dry etching process, by way of example. Since the antireflection layer according to the invention is a conformally deposited layer, there is no risk of overetching and hence an attack of the underlying layer stack or the underlying layer.

In one advantageous manner, implantation is effected through the antireflection layer during the implantation process. In this case, the antireflection layer is to be provided such that it is thin enough that the implantation process is not disturbed.

In one preferred manner, gate structures of transistors are formed with the patterned layer. The sections doped by the method for introducing a dopant are then provided as source/drain regions of the transistors. The method according to the invention makes it possible to fabricate transistors with ever smaller gate lengths with a higher productivity since fewer rejects are produced on account of the improved photoresist patterning.

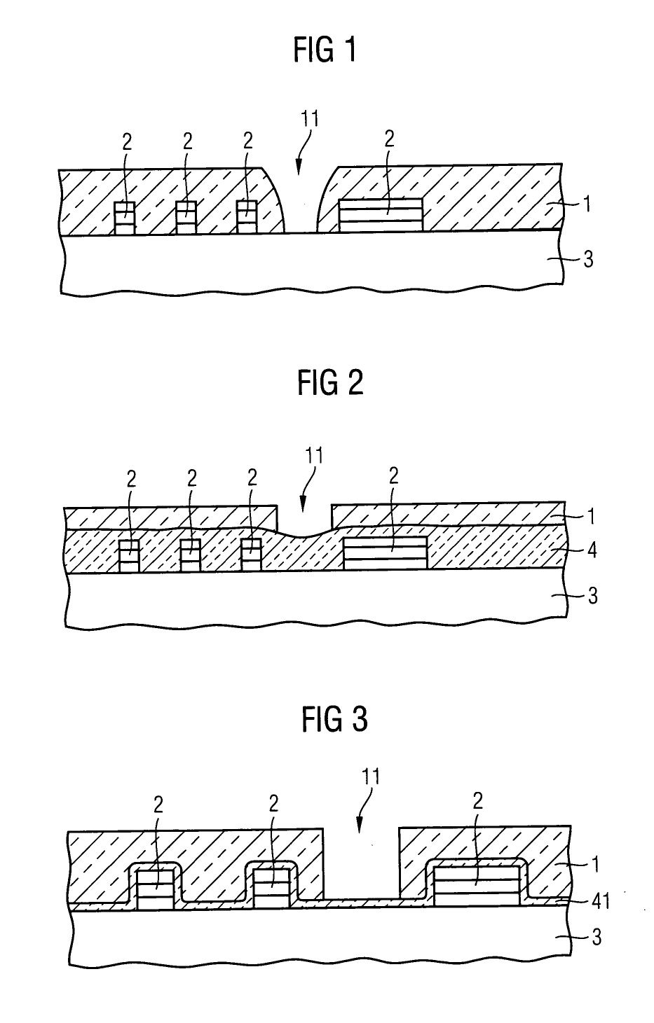

FIGS. 1 and 2 have already been explained in more detail in the Background section.

In one embodiment of a method for patterning a photoresist layer 11, a conformal, organic antireflection layer 41 is applied to a layer stack 2 having a topology. The conformal antireflection layer 41 may be produced by means of a CVD method, by way of example. It is possible to apply a known method for fabricating a carbon hard mask for the application of the organic antireflection layer. With the aid of the conformal organic antireflection layer 41, it becomes possible to pattern the photoresist layer 1 dimensionally accurately. After the exposure and the development of the photoresist layer 1, the structures are contained in the photoresist layer 1 as openings 11. Since backreflections are avoided by virtue of the organic conformal antireflection layer 41, dimensional losses such as, for example, oblique sidewalls of the openings 11 can be avoided. The conformal organic antireflection layer 41 has the advantage that it can be provided in particularly thin fashion, in the range of 10 to 30 nm, and, as a result, for example source/drain regions of transistors can be implanted through the antireflection layer 41. On account of the conformity of the antireflection layer 41, for an oblique implantation, the antireflection layer 41 can be removed by means of an etching step with no risk of overetching and hence incipient etching of the layer stack 2. Further processing processes of the semiconductor wafer 3 are not influenced by the conformal organic antireflection layer 41 since the antireflection layer 41 can be concomitantly removed, for example by incineration, in a simple manner during the removal of the photoresist layer 1.

FIG. 3 illustrates a detail from the semiconductor wafer 3 onto which the patterned layer stack 2 having a topology is arranged. The conformal, organic antireflection layer 41 is provided on the patterned layer stack 2. As can be gathered from FIG. 3, the topology is completely preserved with the conformal antireflection layer 41. The conformal antireflection layer 41 has the same thickness at all places. The photoresist layer 1 illustrated in FIG. 3 is applied to the antireflection layer 41. After the exposure and development, the photoresist layer 1 has the structures in the form of the opening 11 illustrated by way of example. In contrast to conventional patterning methods, the opening 11 produced by the method according to the invention is formed without dimensional losses and with perpendicular sidewalls.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for transferring structures from a photomask into a photoresist layer, the photoresist layer being arranged above a patterned layer or a patterned layer stack above a semiconductor wafer, comprising:
making available the semiconductor wafer with the patterned layer or the patterned layer stack;
applying an organic, conformal antireflection layer to the patterned layer or the patterned layer stack;
applying the photoresist layer to the antireflection layer;
exposing the photoresist layer in sections with the aid of an imaging device and the photomask; and
developing the photoresist layer, the structures being formed as openings in the photoresist layer.

2. The method as claimed in claim 1, wherein the conformal antireflection layer is deposited from a gas phase onto the patterned layer or the patterned layer stack.

3. The method as claimed in claim 2, comprising wherein the conformal antireflection layer is deposited by means of a CVD method.

4. The method as claimed in claim 3, comprising wherein a carbon compound is deposited during the CVD method.

5. The method as claimed in claim 1, wherein the conformal antireflection layer is applied by means of a pyrolysis method.

6. A method for introducing a dopant into sections of the semiconductor wafer or a layer provided above the semiconductor wafer, the patterned layer or the patterned layer stack being provided on the semiconductor wafer or the layer;
wherein the method for transferring structures from a photomask into a photoresist layer as claimed in one of claims 1 to 5 is applied;
an implantation step is carried out in the region of the openings, the dopant passing into the sections; and
the photoresist layer and the conformal antireflection layer are removed.

7. The method as claimed in claim 6, comprising wherein after the development of the photoresist layer and prior to the implantation step, the conformal antireflection layer is removed in the openings in the photoresist layer.

8. The method as claimed in claim 6, comprising wherein implantation is effected through the conformal antireflection layer during the implantation step, the conformal antireflection layer having to be provided in correspondingly thin fashion.

9. The method as claimed in one of claims 6 to 8, comprising wherein the gate structures of transistors are formed with the patterned layer; and
the doped sections are provided as source/drain regions of the transistors.

10. A method for making a semiconductor, including transferring structures from a photomask into a photoresist layer, comprising:
providing a semiconductor wafer with a patterned layer;
applying an organic, conformal antireflection layer to the patterned layer;
applying the photoresist layer to the antireflection layer;
exposing the photoresist layer using an imaging device and the photomask; and
developing the photoresist layer, the structures being formed as openings in the photoresist layer.

11. The method as claimed in claim 10, comprising wherein the patterned layer is a patterned layer stack.

12. The method as claimed in claim 10, comprising wherein exposing the photoresist layers includes exposing the photoresist layers in sections.

13. The method as claimed in claim 10, wherein the conformal antireflection layer is deposited from a gas phase onto the patterned layer or the patterned layer stack.

14. The method as claimed in claim 13, comprising wherein the conformal antireflection layer is deposited using a CVD method.

15. The method as claimed in claim 14, comprising wherein a carbon compound is deposited during the CVD method.

16. The method as claimed in claim 10, wherein the conformal antireflection layer is applied using a pyrolysis method.

17. A method for introducing a dopant into sections of a semiconductor wafer, a patterned layer provided on the semiconductor wafer, comprising:
transferring structures from a photomask into a photoresist layer, comprising:
providing a semiconductor wafer with a patterned layer;
applying an organic, conformal antireflection layer to the patterned layer;
applying the photoresist layer to the antireflection layer;
exposing the photoresist layer using an imaging device and the photomask; and
developing the photoresist layer, the structures being formed as openings in the photoresist layer;
carrying out an implantation, in the region of the openings, the dopant passing into the sections; and
removing the photoresist layer and the conformal antireflection layer.

18. The method as claimed in claim 17, comprising wherein after the development of the photoresist layer and prior to the implantation, the conformal antireflection layer is removed in the openings in the photoresist layer.

19. The method as claimed in claim 17, comprising wherein implantation is effected through the conformal antireflection layer during the implantation, the conformal antireflection layer having to be provided in correspondingly thin fashion.

20. The method as claimed in one of claims 17, comprising wherein the gate structures of transistors are formed with the patterned layer; and the doped sections are provided as source/drain regions of the transistors.

21. A method for transferring structures from a photomask into a photoresist layer, the photoresist layer being arranged above a patterned layer or a patterned layer stack above a semiconductor wafer, comprising:
providing the semiconductor wafer with the patterned layer or the patterned layer stack;
means for applying an organic, conformal antireflection layer to the patterned layer or the patterned layer stack;
means for applying the photoresist layer to the antireflection layer;
means for exposing the photoresist layer in sections using an imaging device and the photomask; and
means for developing the photoresist layer, the structures being formed as openings in the photoresist layer.
